(19) United States
(12) Patent Application Publication
(10) Pub. No.: US 2016/0131692 A1
(43) Pub. Date: May 12, 2016

(54) Cable Monitoring Apparatus

(71) Applicant: Cameron International Corporation, Houston, TX (US)

(72) Inventor: Andrew Jaffrey, Oldmeldrum (GB)

(73) Assignee: Cameron International Corporation, Houston, TX (US)

(21) Appl. No.: 14/539,749

(22) Filed: Nov. 12, 2014

(51) Int. Cl. G01R 31/02; G01R 31/12

(52) U.S. Cl. CPC G01R 31/021; G01R 31/1272

(57) ABSTRACT

A monitoring apparatus is connectable in-line with the cable. The monitoring apparatus includes a measuring unit to measure a characteristic of the cable and a storage unit to store the measured characteristic of the cable.

BACKGROUND

This section is intended to introduce the reader to various aspects of art that may be related to various aspects of the presently described embodiments. This discussion is believed to be helpful in providing the reader with background information to facilitate a better understanding of the various aspects of the present embodiments. Accordingly, it should be understood that these statements are to be read in this light, and not as admissions of prior art.

In order to meet consumer and industrial demand for natural resources, companies often invest significant amounts of time and money searching for and extracting oil, natural gas, and other subterranean resources from the earth. Particularly, once a desired subterranean resource is discovered, drilling and production systems are often employed to access and extract the resource. These systems may be located onshore or offshore depending on the location of a desired resource. Further, such systems generally include a wellhead assembly through which the resource is extracted. These wellhead assemblies may include a wide variety of components, such as various casings, valves, fluid conduits, and the like, that control drilling or extraction operations.

More particularly, wellhead assemblies typically include and connect to pressure-control equipment, such as a blowout preventer, to help control the flow of fluid (e.g., oil or natural gas) from a well. As will be appreciated, uncontrolled releases of oil or gas from a well via the wellhead assembly (also referred to as a blowout) are undesirable. Further, components and equipment in use with and coupled to the wellhead assembly benefits from robust design, to reduce the likelihood that oil or gas may be unintentionally released through these other components. As such, as there are numerous manufacturers for these components and equipment, in addition to the wellhead assemblies and blowout preventers themselves, measures are taken to help ensure that all of the equipment in use and the connections between the equipment are robust and field ready.

### BRIEF DESCRIPTION OF THE DRAWINGS

For a detailed description of the preferred embodiments of the present disclosure, reference will now be made to the accompanying drawings in which:

FIG. 1 shows a block diagram of a resource extraction system in accordance with one or more embodiments of the present disclosure;

FIGS. 2A and 2B generally show a coupling of a well capping system to a wellhead in accordance with one or more embodiments of the present disclosure;

FIG. 3 is a schematic view of an embodiment of an offshore system for drilling and/or producing a subterranean wellbore in accordance with one or more embodiments of the present disclosure;

FIG. 4 shows a subsea blowout preventer stack in accordance with one or more embodiments of the present disclosure;

FIG. 5 shows a riser connector in accordance with one or more embodiments of the present disclosure;

FIG. 6 shows a system including a cable to communicate power and/or data between electronic components in accordance with one or more embodiments of the present disclosure;

FIG. 7 shows a system to monitor a condition of a cable in accordance with one or more embodiments of the present disclosure; and

FIG. 8 shows a system to monitor a condition of a cable in accordance with one or more embodiments of the present disclosure.

### DETAILED DESCRIPTION

The following discussion is directed to various embodiments of the present disclosure. The drawing figures are not necessarily to scale. Certain features of the embodiments may be shown exaggerated in scale or in somewhat schematic form and some details of conventional elements may not be shown in the interest of clarity and conciseness. Although one or more of these embodiments may be preferred, the embodiments disclosed should not be interpreted, or otherwise used, as limiting the scope of the disclosure, including the claims. It is to be fully recognized that the different teachings of the embodiments discussed below may be employed separately or in any suitable combination to produce desired results. In addition, one skilled in the art will understand that the following description has broad application, and the discussion of any embodiment is meant only to be exemplary of that embodiment, and not intended to intimate that the scope of the disclosure, including the claims, is limited to that embodiment.

Certain terms are used throughout the following description and claims to refer to particular features or components. As one skilled in the art will appreciate, different persons may refer to the same feature or component by different names. This document does not intend to distinguish between components or features that differ in name but are the same structure or function. The drawing figures are not necessarily to scale. Certain features and components herein may be shown exaggerated in scale or in somewhat schematic form and some details of conventional elements may not be shown in interest of clarity and conciseness.

In the following discussion and in the claims, the terms “including” and “comprising” are used in an open-ended fashion, and thus should be interpreted to mean “including, but not limited to . . . . ” Also, the term “couple” or “couples” is intended to mean either an indirect or direct connection. In addition, the terms “axial” and “axially” generally mean along or parallel to a central axis (e.g., central axis of a body or a port), while the terms “radial” and “radially” generally mean perpendicular to the central axis. For instance, an axial distance refers to a distance measured along or parallel to the central axis, and a radial distance means a distance measured perpendicular to the central axis. The use of “top,” “bottom,” “above,” “below,” and variations of these terms is made for convenience, but does not require any particular orientation of the components.

Reference throughout this specification to “one embodiment,” “an embodiment,” or similar language means that a particular feature, structure, or characteristic described in connection with the embodiment may be included in at least one embodiment of the present disclosure. Thus, appearances of the phrases “in one embodiment,” “in an embodiment,” and similar language throughout this specification may, but do not necessarily, all refer to the same embodiment.

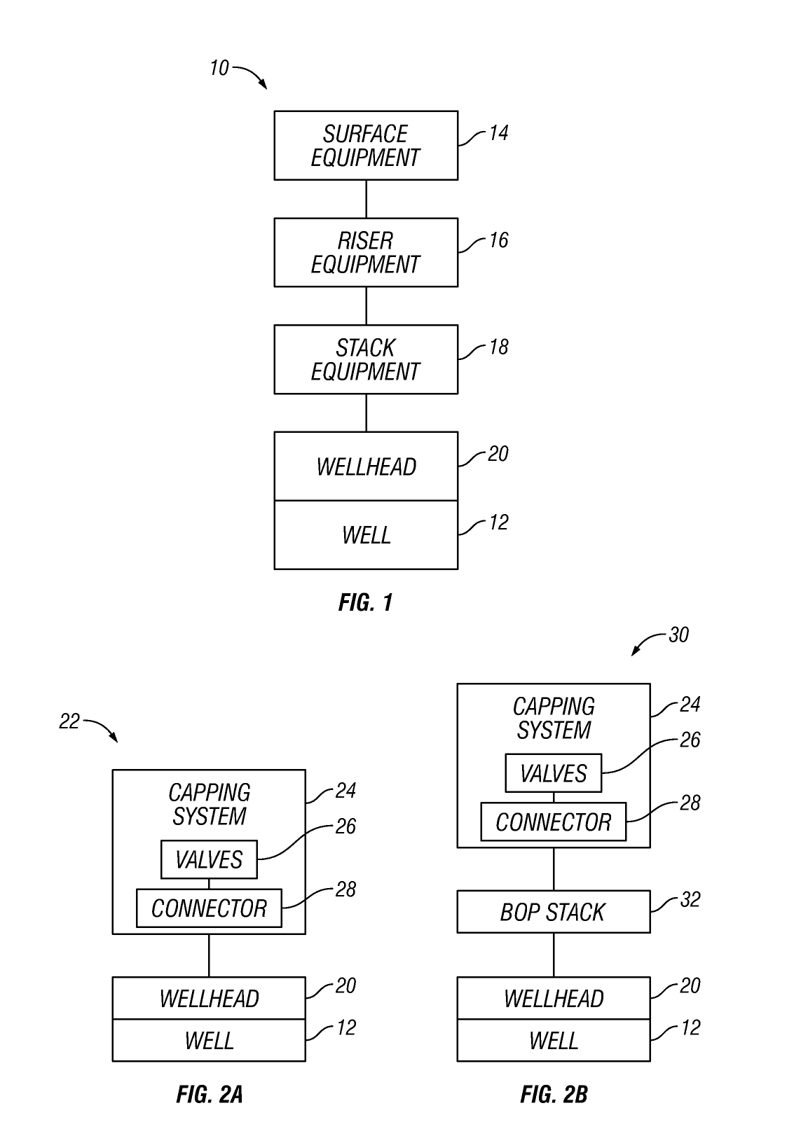

Turning now to the present figures, a resource extraction system 10 is illustrated in FIG. 1 in accordance with one or more embodiments of the present disclosure. Notably, the system 10 facilitates extraction of a resource, such as oil or natural gas, from a well 12. As depicted, the system 10 may be a subsea system that includes surface equipment 14, riser equipment 16, and/or stack equipment 18, for extracting the resource from the well 12 via a wellhead 20. In one subsea resource extraction application, the surface equipment 14 may be mounted to a drilling rig above the surface of the water, the stack equipment 18 may be coupled to the wellhead 20 near the sea floor, and the surface equipment 14 and the stack equipment 18 may be coupled to one another via the riser equipment 16.

As will be appreciated, the surface equipment 14 may include a variety of devices and systems, such as pumps, power supplies, cable and hose reels, control units, a diverter, a gimbal, a spider, and the like. Similarly, the riser equipment 16 may also include a variety of components, such as riser joints, fill valves, control units, and a pressure-temperature transducer, to name but a few. The riser equipment 16 may facilitate transmission of the extracted resource to the surface equipment 14 from the stack equipment 18 and the well 12. The stack equipment 18, in turn, may include a number of components, such as blowout preventers, production trees (also known as “Christmas” trees), and the like for extracting the desired resource from the wellhead 20 and transmitting the resource to the surface equipment 14 via the riser equipment 16.

In one or more embodiments, if a blowout occurs at a well, a capping system may be used in some instances to seal the well and reestablish control. Examples of the use of such capping systems are provided in FIGS. 2A and 2B. In one embodiment of the present disclosure represented by a block diagram 22 in FIG. 2A, a capping system 24 may be attached to the wellhead 20 (such as following removal of the stack equipment 18 from the wellhead 20). The capping system 24 may include one or more valves 26, such as a blowout preventer, for controlling flow from the wellhead 20. The capping system 24 may also include an adapter or connector 28 that facilitates connection of the capping system 24 onto the wellhead 20. When not in use, the capping system 24 may be kept on “stand-by” as safety equipment for responding to a blowout. And though the capping system 24 may be used with subsea well installations, it is noted that the capping system 24 may also be used with other well installations (e.g., equipment of surface wells).

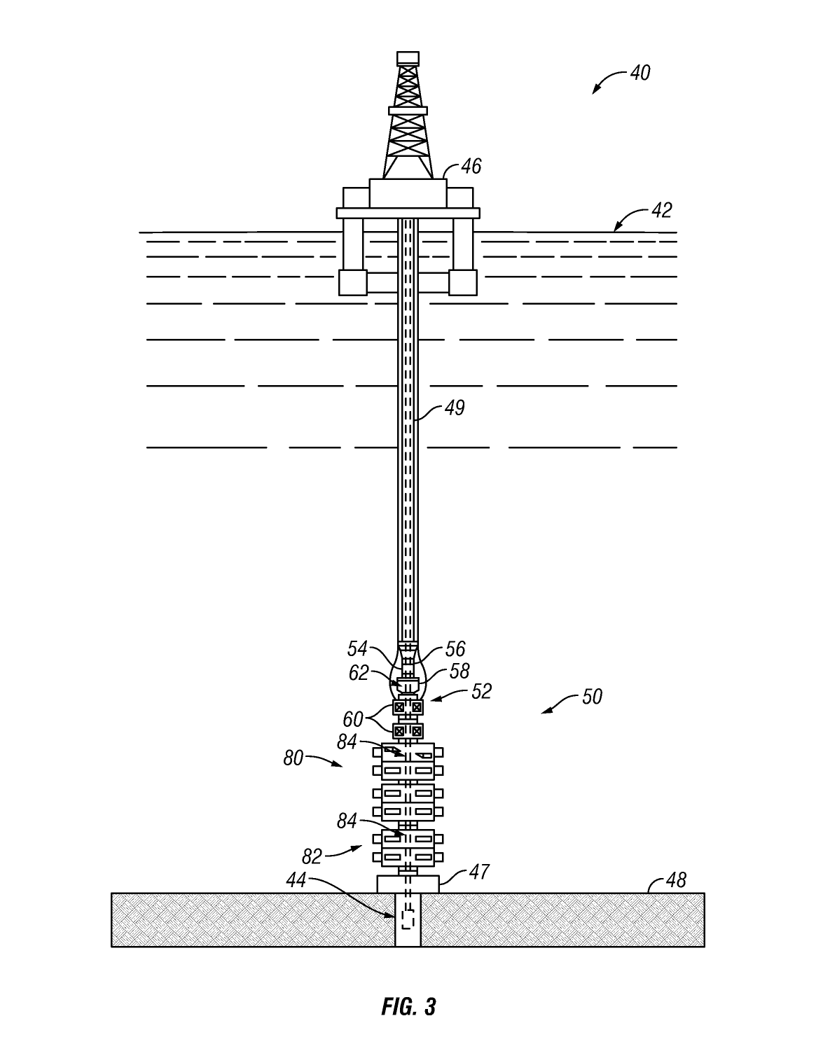

Referring now to FIG. 3 as another example, an embodiment of an offshore system 40 for drilling and/or producing a wellbore 44 in accordance with one or more embodiments of the present disclosure is shown. In this embodiment, system 40 includes an offshore vessel or platform 46 at the sea surface 42 and a subsea BOP stack assembly 50 mounted to a wellhead 47 at the sea floor 48. The BOP stack assembly 50 is mounted to wellhead 47 and is designed and configured to control and seal wellbore 44, thereby decreasing the risk of an unintended release of hydrocarbon fluids (liquids and gases). In this embodiment, the BOP stack assembly 50 may include a lower marine riser package (LMRP) 52, a primary BOP or BOP stack 80, and a secondary BOP or BOP stack 82, with a main bore 84 extending therethrough. The LMRP 52 may include a riser flex joint 56, a riser adapter 54, an annular BOP 58, and a pair of redundant control units or pods 60. A flow bore 62 extends through the LMRP 52 from a riser 49 at the upper end of the LMRP 52 to a connection at the lower end of the LMRP 52. The riser adapter 54 extends upward from the flex joint 56 and is coupled to the lower end of the riser 49. The flex joint 56 allows the riser adapter 54 and the riser 49 connected thereto to deflect angularly relative to the LMRP 52 while wellbore fluids flow from the wellbore 44, through the BOP stack assembly 50, into the riser 49. The secondary BOP stack 82 serves as a backup to the primary BOP stack 80 and the LMRP 52 in the event the primary BOP stack 80 and/or the LMRP 52 fail, malfunction, or lose control communication with the vessel 46. Accordingly, the secondary BOP stack 82 may also be referred to as a backup BOP stack or a BOP stack of last resort.

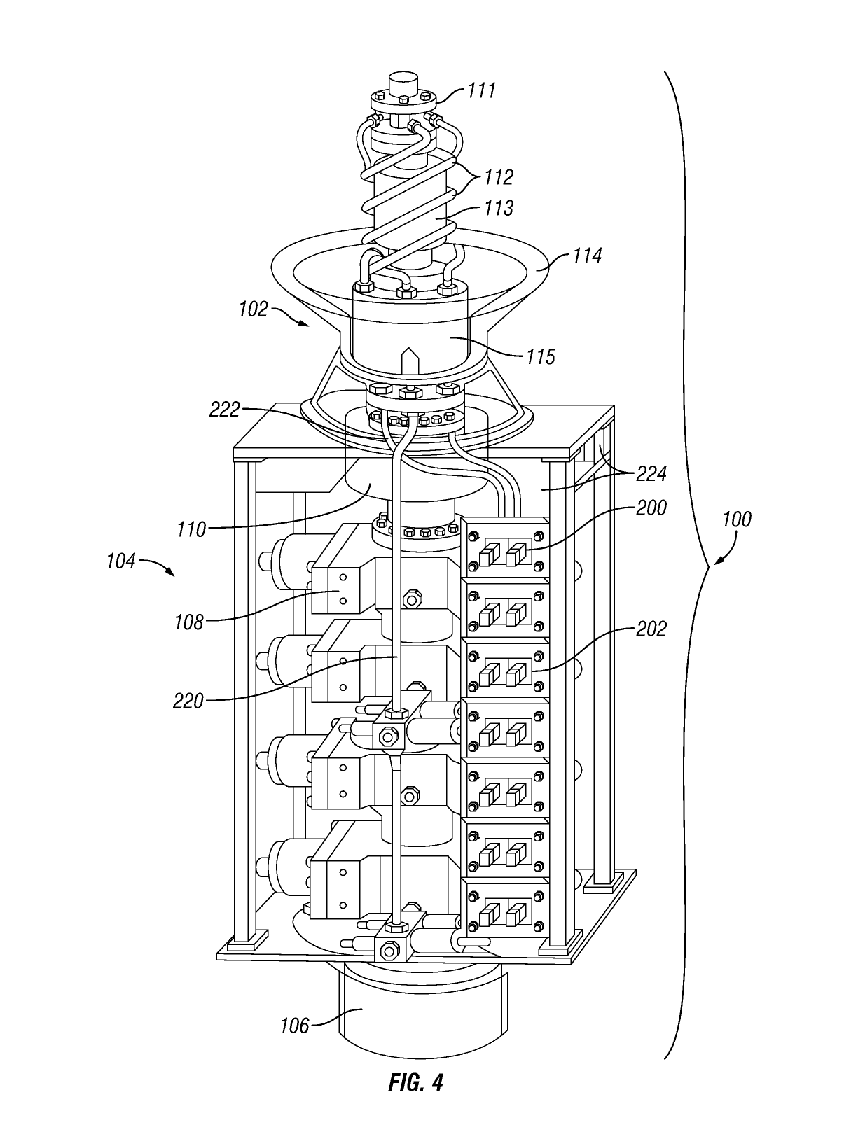

Referring now to FIG. 4, a subsea blowout preventer stack (BOP stack) 100 in accordance with one or more embodiments of the present disclosure is shown. Variations of the architecture and components of modular retrievable element control system 200 may be utilized subsea, e.g. in production tree, production riser, and subsea manifold control interface applications. In one or more embodiments, the BOP stack 100 may include a riser connector 102, a BOP assembly 104, and a wellhead connector 106.

The BOP assembly 104 may accept and allow the use of distributed functional control modules 200 that are remotely operated vehicle (ROV) retrievable. The use of the distributed functional control modules 200, and/or the modular distributed control system architecture, in subsea BOP Stack applications may allow for the re-configuration of existing BOP stack arrangement designs to reduce weight and complexity in the integration and unitization of the elements required to form the overall BOP stack 100.

The BOP assembly 104 may be unitized and include one or more of the following elements, such as the hydraulic connector 106 to interface to the subsea wellhead, one or more blowout preventers 108 (e.g. ram type blowout preventers), annular 110 or spherical type blowout preventers, a plurality of hydraulic connectors to interface to a marine riser (not shown in the figures), and/or hydraulically operated gate type valves for isolation and access for choke and kill functions. The riser connector 102 may include one or more of the following, such as a riser adapter 111, a guideline-less reentry assembly 114, and a multi-bore connector 115. A flex joint 113 may be positioned intermediate the riser adapter 111 and the multi-bore connector 115. One or more flex loops 112 may be present and in fluid communication with ports on the riser adapter 111. The multi-bore connector 115 may provide an interface to the BOP assembly 104.

The BOP assembly 104 may be further adapted to receive one or more control modules 200 into one or more docking stations 202 and/or other modules, e.g. the annular preventer 110, the RAM preventer 108, the blowout preventers (not specifically shown), connectors (not specifically shown), “Fail Safe” gate valves (not specifically shown), sub system interface valves (not specifically shown), or the like, or combinations thereof. One or more lines 220, e g kill and/or choke lines, may be present as well as various control pathways, such as hydraulic conduit 222 and/or multiplexer (MUX) cables. Hang-off beams 224 may also be provided to allow for support of BOP assembly 104 during certain operations, e.g. in a moon pool area such as for staging and/or testing prior to running.

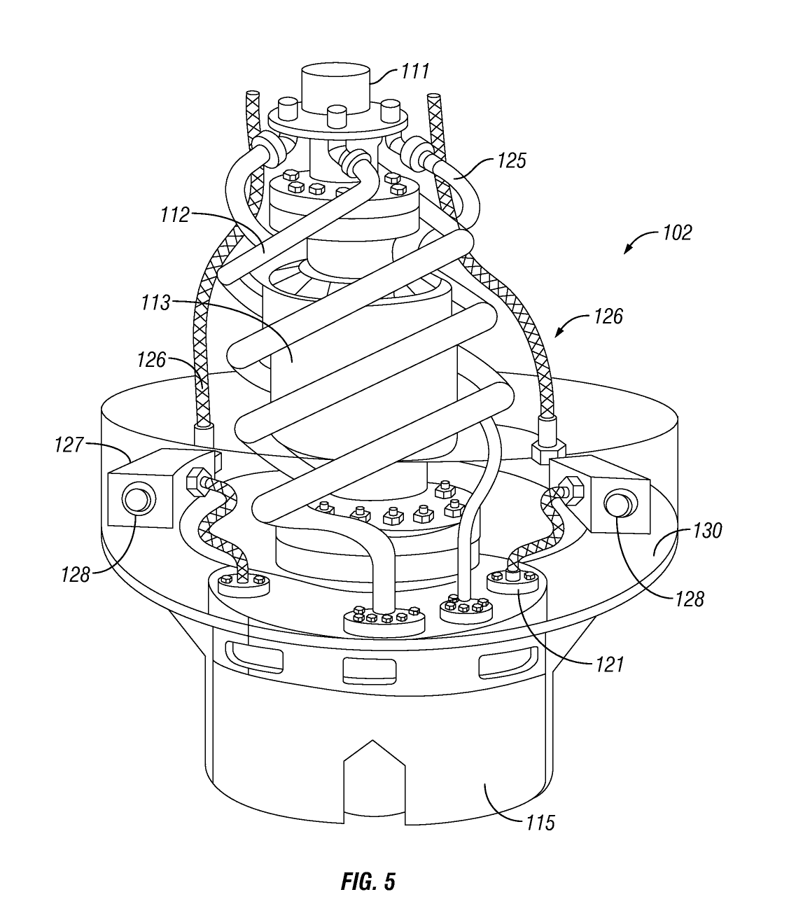

Referring now to FIG. 5, a riser connector 102 may be adapted to provide a connector, such as riser adapter 111, to interface with a marine riser (not shown in FIG. 5). In one embodiment, the riser connector 102 may include one or more MUX cables 126 and/or one or more hydraulic conduit hoses 125. The riser connector 102 may also incorporate integral connection receptacles for choke/kill, hydraulic, electric, and boost line conduit interfaces. In one embodiment, the riser connector 102 is configured with connector 115 as a multi-bore connector rather than single bore connector, although either configuration may be used. This may allow for the riser connector 102 to absorb loading and separating forces, as well as bending moments, within the body where substantial section modulus exists. Further, this configuration may decrease the need for a substantial fabricated structure to alleviate the potential for separation of a line holding a high pressure, e.g. line 220 (FIG. 4).

In one embodiment, one or more subsea wet mateable connectors 121 may be included within the riser connector 102 for interfacing with the BOP assembly 104 (FIG. 4). For example, this interface may be used to supply power and/or communications to the control modules 200 (FIG. 4) included on the BOP assembly 104. The riser connector 102 may also include a riser connector control module 128, which may include and/or be integral with a junction box 127 and/or a subsea electronics module. The riser connector control module 128 may allow control of the riser connector 102, and a lower marine riser package may function independent of the BOP stack 100 (FIG. 4) in the event the marine riser is disconnected from the BOP stack 100 and pulled back to the surface.

The subsea electronics module 127 may provide for connections, such as electrical connections, and may be equipped with connector receptacles for interfacing to ROV devices, e.g. ROV retrievable control modules 200 (FIG. 4) to facilitate control of riser connector functions. As such, the subsea electronics module 127 may provide one or more interfaces from the multiplex cables 126 to a lower marine riser package that includes the multibore riser connector 115. As such, in one or more embodiments, the multiplex cables 126 may include pressure balanced oil-filled cables.

An apron plate 130 may be provided for mounting the junction boxes 127, such as to provide a transition from main multiplex control cable connectors to the wet mateable assemblies located in the multi-bore connector 115. Power and other signals to the riser connector control module 128 may be provided, such as by using one or more pressure balanced oil-filled cables connected to the electrical junction boxes 127 mounted on the apron plate 130. In one embodiment, two junction boxes 127 may be provided for redundancy and each may be distinguished from the other, e.g. labeled or provided with different colors. The riser connector 102 may include the flex joint 113 and one or more flex loops 112, such as to allow for angular movement to compensate for vessel offset. The upper flange adapter or flex joint top connection may interface to a flange of riser adapter 111 containing kick-out flanged assemblies for connection of lines 220 (FIG. 4) interfacing with the marine riser, e.g. formed hard pipe flow-loops that interface choke and kill line 220 to the main marine riser.

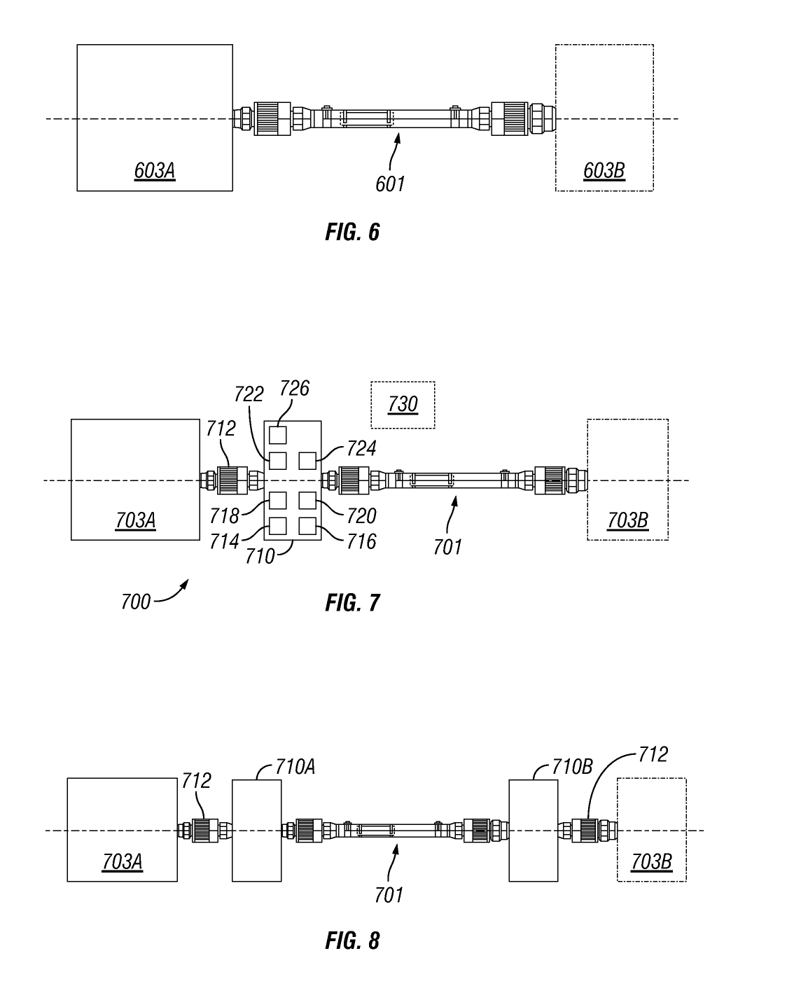

Referring now to FIG. 6, an embodiment is shown in which a cable 601, such as a pressure balanced oil-filled cable, is used to communicate power and/or data between electronic components and/or housings 603A and 603B. For example, the electronic components 603A and 603B may be included within a subsea resource extraction system. In such an embodiment, one and/or both of the electronic components 603A and 603B may include a subsea electronics module and/or a riser control box.

Referring now to FIG. 7, a system 700 to monitor a condition of a cable 701 in accordance with one or more embodiments of the present disclosure is shown. The cable 701 may be used to communicate power and/or data between electronic components and/or housings 703A and 703B. The cable 701 may be a pressure balanced oil-filled cable, such as shown in this embodiment, and/or may be any other cable capable of transferring power and/or data. One and/or both of the electronic components 703A and 703B may include a subsea electronics module and/or a riser control box, and/or any other component discussed above with respect to FIGS. 1-6.

Further, as shown, the system 700 may include a monitoring apparatus 710. The monitoring apparatus 710 may be used to monitor one or more conditions and/or components of the cable 701, such as to determine if and when the cable 701 may need to be replaced within the system 700. In this embodiment, the monitoring apparatus 710 may be connectable in-line with the cable 701, such as connectable in series with the cable 701. In another embodiment, the monitoring apparatus 710 may be connectable in parallel with the cable 701.

The condition of the cable 701 may degrade and fail due to several factors, particularly in a pressurized subsea environment, such as degradation of the insulation resistance of the cable 701, fluid ingress into the cable 701, and/or external impacts experienced by the cable 701. In one embodiment, the monitoring apparatus 710 may be used to monitor a condition of one or more data conductors and/or one or more power conductors included within the cable 701. The monitoring apparatus 710 may then be able to determine if one or more data conductors and/or one or more power conductors has degraded and/or failed.

As the monitoring apparatus 710 may be used to monitor the conditions and/or components of the cable 701, the monitoring apparatus 710 may be directly connected to one of the ends of the cable 701, as shown. This may enable the monitoring apparatus 710 to send signals into and/or receive signals from the cable 701 without interference of other components therebetween. As the monitoring apparatus 710 may be introduced into the system 700 between the electronic components 703A and 703B, an adapter 712 may also be included within the system 700. The adapter 712 may be included between the monitoring apparatus 710 and the electronic component 703A, such as to establish electronic communication between the electronic components 703A and 703B through the cable 701, the monitoring apparatus 710, and the adapter 712.

The monitoring apparatus 710 may include one or more units, such as formed separately or together, to facilitate monitoring the conditions and/or components of the cable 701. For example, as shown in FIG. 7, the monitoring apparatus 710 may include a measuring unit 714, a storage unit 716, and/or an output unit 718. The measuring unit 714 may be used to measure a characteristic of the cable 701 based upon a signal sent into the cable 701 and/or received from the cable 701. For example, the measuring unit 714 may be able to measure one or more of the following characteristics of the cable 701 and/or components of the cable 701, including, but not limited to: impedance, resistance, capacitance, inductance, propagation speed, propagation delay, and delay skew related to the cable.

In one or more embodiments, the measuring unit 714 may measure one or more characteristics of the cable 701, in which the measuring unit 714 and/or another unit (e.g., a determining unit 726) of the monitoring apparatus 710 may compare the measured characteristic of the cable 701 with a predetermined value and/or predetermined range for the measured characteristic. Based upon this comparison, the measuring unit 714 and/or another unit (e.g., the determining unit 726) of the monitoring apparatus 710 may determine the condition of the cable 701, such as if the cable 701 is acceptable for service and/or needs replacing. For example, the resistance of the cable 701 may be a characteristic that may be measured by the measuring unit 714 of the monitoring unit 710. If the measured resistance of the cable 701 is above a predetermined value, and/or is not within a predetermined range, then the condition of the cable 701 may be determined to need service and/or replacement. Additionally or alternatively, the propagation delay of the cable 701 may be a characteristic that may be measured by the measuring unit 714 of the monitoring unit 710. If the measured propagation delay of the cable 701 is above a predetermined value, and/or is not within a predetermined range, then the condition of the cable 701 may be determined to need service and/or replacement. The condition of the cable 701 may be determined to need service and/or replacement due to several factors, such as degradation of insulation resistance of the cable 701, fluid ingress into the cable 701, and/or external impacts to the cable 701.

In one embodiment, the monitoring apparatus 710 may give an evaluation that indicates that the condition of the cable is good (e.g., monitoring apparatus 710 indicates a green light), the condition of the cable is satisfactory but close to replacement (e.g., monitoring apparatus 710 indicates a yellow light), and/or the condition of the cable is in need of replacement (e.g., monitoring apparatus 710 indicates a red light).

The storage unit 716 may be used to store the measured characteristic of the cable 701. For example, in an embodiment in which the monitoring apparatus 710 may not be in immediate vicinity to provide the measured characteristic of the cable 701, the storage unit 716 may be used to temporarily and/or permanently store the measured characteristic of the cable 701. As such, in one or more embodiments, the storage unit 716 may include a non-volatile memory device to enable the measured characteristics and data collected by the monitoring apparatus 710 to be downloaded and received, with or without power to the monitoring apparatus 710.

The output unit 718 of the monitoring apparatus 710 may be used to output the measured characteristic of the cable 701 from the monitoring apparatus 710. The output unit 718 may enable data to be output and/or downloaded in real-time, pseudo real-time, and/or at a later time or date. The output unit 718 may therefore include a direct cable connection device to enable a cable to be input into the output unit 718 of the monitoring apparatus 710 to receive and/or download the measured characteristics and/or data collected by the monitoring apparatus 710. Additionally or alternatively, the output unit 718 may include a wireless communication device, in which the wireless communication device may include an inductive coupling unit, a radio-frequency unit, a radio-frequency identification unit, and/or a near-field communication unit (e.g., Bluetooth technology).

As the monitoring apparatus 710 may be used to store data and/or the measured characteristics to be downloaded and received at a later time, the monitoring apparatus 710 may include a timing unit 720. The timing unit 720 may enable the monitoring apparatus 710 to schedule monitoring activities of the cable 701. Further, the timing unit 720 may be used to include a time stamp with the measured characteristics and/or data of the cable 701. The time stamp may then be used to identify when the measured characteristics and/or data of the cable 701 were measured or gathered. Further, in one or more embodiments, the monitoring apparatus 710 may include an identification unit 722, such as to include a unique identifier with the measured characteristics and/or data. In an embodiment in which a system includes multiple cables and multiple monitoring apparatuses, the identification unit 722 may include a unique identifier with the measured characteristics and/or data to determine which monitoring apparatus collected the data, and in turn, which cable is being monitored by the monitoring apparatus. Further, in one or more embodiments, the unique identifier of the identification unit 722 may be configurable, in that the unique identifier may be selectively changed as desired by a user.

As the output unit 718 of the monitoring apparatus 710 may include a wireless communication device, the system 700 may include a corresponding wireless device 730 to communicate with the wireless communication device of the monitoring apparatus 710 and receive the measured characteristic of the cable. For example, the wireless device 730 may include a wireless handheld device that may be moved into the vicinity of the monitoring apparatus 710 to receive the data from the monitoring apparatus 710. This may involve using a wireless device 730 subsea, such as with a remote-operated vehicle (ROV) and/or an autonomous underwater vehicle (AUV), to receive and download data from the monitoring apparatus 710. Additionally or alternatively, when the system 700 is pulled to the surface (such as when servicing the system 700 and/or any other components used in conjunction with the system 700) the wireless device 730 may be used to receive and download data from the monitoring apparatus 710.

In an embodiment in which the wireless communication device of the monitoring apparatus 710 includes passive technology, such as a radio-frequency identification unit, the wireless device 730 may be used to activate and/or stimulate the wireless communication device of the monitoring apparatus 710 to receive and/or download data from the monitoring apparatus 710. Further, as the monitoring apparatus 710 may include an identification unit 722, the wireless device 730 may be used to download and receive data from multiple monitoring apparatuses, each of the data sets including a unique identifier to identify the monitoring apparatus and the cable being monitored.

Referring still to FIG. 7, the monitoring apparatus 710 may include a power supply unit 724 to provide power, at least partially, for the monitoring apparatus 710. In one embodiment, the power supply unit 724 may be used to receive power, at least partially, from the cable 701, such as to receive power from a power conductor of the cable 701. Additionally or alternatively, the power supply unit 724 may include one or more power sources, such as a battery (e.g., rechargeable battery). Power from other sources may also be provided to the power supply unit 724 to power the monitoring apparatus 710, such as using techniques that may include direct connection and/or inductive coupling.

As discussed above, the monitoring apparatus 710 may be used to monitor a condition of the cable 701, in which the cable 701 may be a pressure balanced oil-filled cable. In such an embodiment, the monitoring apparatus 710 may include one or more appropriate connectors to connect, such as directly connect, with the pressure balanced oil-filled cable. In particular, the monitoring apparatus 710 may include one or more API 16D connectors. Further, as the monitoring apparatus 710 may be used to monitor the condition of other cables, the monitoring apparatus 710 may include one or more replaceable connectors to enable the monitoring apparatus 710 to connect with different cables. As the monitoring apparatus 710 may directly connect to a cable, the connectors of the monitoring apparatus 710 may include the appropriate (e.g., same) amount and size of pins and/or sockets as that of the corresponding cable.

Further, in an embodiment in which a measurement of the cable 701 requires a loop to be formed with respect to the cable 701, more than one monitoring apparatus 710 may be used to monitor the condition of the cable 701. For example, as shown in FIG. 8, a first monitoring apparatus 710A may be connected to one end of the cable 701, and a second monitoring apparatus 710B may be connected to another end of the cable 701. The first monitoring apparatus 710A and the second monitoring apparatus 710B may then be able to communicate with each other, such as through the cable 701, through another cable, and/or wirelessly with each other. As such, in one embodiment, the first monitoring apparatus 710A may be able to send signals through the cable 701 to the second monitoring apparatus 710B to monitor the condition of the cable 701. If necessary, the second monitoring apparatus 710B may then send the same signal or a corresponding signal back to the first monitoring apparatus 710A to measure a characteristic and monitor the condition of the cable 701. In an embodiment in which more than one monitoring apparatus 710 is used to monitor the condition of the cable 701, then more than one adapter 712 may also be used to connect the electronic components 703A and 703B, as shown.

The present disclosure, while discussed in relation to the use and monitoring of a condition of a cable, such as a pressure balanced oil-filled cable, is not so limited. For example, an apparatus and/or system in accordance with the present disclosure may be used with other types of cables and/or components, whether subsea and/or on the surface. For example, an apparatus in accordance with the present disclosure may be able to monitor the condition of a cable (e.g., non-pressure balanced oil-filled cable) that may be used within processing, production, and/or surface equipment. Accordingly, the present disclosure is not limited to only the above figures and descriptions shown above.

While the aspects of the present disclosure may be susceptible to various modifications and alternative forms, specific embodiments have been shown by way of example in the drawings and have been described in detail herein. But it should be understood that the invention is not intended to be limited to the particular forms disclosed. Rather, the invention is to cover all modifications, equivalents, and alternatives falling within the spirit and scope of the invention as defined by the following appended claims.

1. A system to monitor a condition of a cable, the system comprising:
a monitoring apparatus connectable in-line with the cable, the monitoring apparatus comprising:
a measuring unit to measure a characteristic of the cable; and
a storage unit to store data related to the measured characteristic of the cable.

2. The system of claim 1, the monitoring apparatus further comprising a determining unit to determine a condition of the cable based upon a comparison of the measured characteristic with a predetermined value for the characteristic.

3. The system of claim 1, wherein the characteristic of the cable measured by the measuring unit comprises at least one of impedance, resistance, capacitance, inductance, propagation speed, propagation delay, and delay skew.

4. The system of claim 1, wherein the monitoring apparatus is configured to monitor a condition of the cable related to at least one of degradation of insulation resistance of the cable, fluid ingress into the cable, and external impacts to the cable.

5. The system of claim 1, wherein the monitoring apparatus is configured to monitor a condition of a data conductor and a power conductor of the cable.

6. The system of claim 5, wherein the monitoring apparatus further comprises a power supply unit to power the monitoring apparatus, wherein the power supply unit is configured to receive power from at least one of the power conductor of the cable and an external source.

7. The system of claim 1, wherein the monitoring apparatus further comprises a timing unit configured to include a time stamp with the measured characteristic of the cable, and wherein the measuring unit of the monitoring apparatus comprises a unique identifier to identify the cable.

8. The system of claim 1, wherein the measuring unit of the monitoring apparatus measures the characteristic of the cable based upon at least one of a signal sent into the cable and a signal received from the cable.

9. The system of claim 1, wherein the storage unit comprises an electronic memory storage unit comprising a non-volatile memory device.

10. The system of claim 1, the monitoring apparatus further comprising an output unit to output the measured characteristic of the cable from the monitoring apparatus, wherein the output unit of the monitoring apparatus comprises a wireless communication device.

11. The system of claim 10, wherein the wireless communication device comprises at least one of an inductive coupling unit, a radio-frequency identification unit, and a near-field communication unit.

12. The system of claim 10, further comprising a wireless device to communicate with the wireless communication device of the monitoring apparatus and receive the measured characteristic of the cable.

13. The system of claim 1, wherein the cable comprises a pressure balanced oil-filled cable, and wherein the monitoring apparatus comprises an API 16D connector to connect with the pressure balanced oil-filled cable.

14. The system of claim 1, wherein the monitoring apparatus is connected in-line with the cable between a first subsea component and a second subsea component.

15. The system of claim 14, further comprising more than one monitoring apparatus with a monitoring apparatus connected to each end of the cable and configured to communicate with each other through the cable.

16. A monitoring apparatus connectable with a cable to monitor a condition of the cable, the monitoring apparatus comprising:
a measuring unit to measure a characteristic of the cable;
a determining unit to determine a condition of the cable based upon a comparison of the measured characteristic with a predetermined value for the characteristic;
a storage unit to store data related to the measured characteristic of the cable; and
an output unit to output the data related to the measured characteristic of the cable from the monitoring apparatus.

17. The monitoring apparatus of claim 16, further comprising:
a power supply unit to power the monitoring apparatus, wherein the power supply unit is configured to receive power from at least one of a power conductor of the cable and an external source;
a timing unit configured to at least one of schedule when to measure the characteristic of the cable and include a time stamp with the measured characteristic of the cable; and
an identification unit to identify the cable.

18. The monitoring apparatus of claim 16, wherein the storage unit comprises an electronic memory storage unit comprising a non-volatile memory device.

19. The monitoring apparatus of claim 16, wherein the output unit of the monitoring apparatus comprises a wireless communication device.

20. The monitoring apparatus of claim 19, wherein a wireless device is configured to communicate with the wireless communication device of the monitoring apparatus and receive the measured characteristic of the cable.
